(19) United States
(12) Patent Application Publication
(10) Pub. No.: US 2004/0245613 A1
(43) Pub. Date: Dec. 9, 2004

(54) Chip scale package and method of fabricating the same

(76) Inventor: Kyu-Han Lee, Siheung-shi (KR)

Correspondence Address: BAKER & DANIELS, 300 NORTH MERIDIAN STREET, SUITE 2700, INDIANAPOLIS, IN, 46204-1782, US

(21) Appl. No.: 10/845,916

(22) Filed: May 14, 2004

(30) Foreign Application Priority Data
May 14, 2003 (KR) 2003-0030430

(51) Int. Cl. H01L 21/44; H01L 23/02; H01L 23/52; H01L 29/40

(52) U.S. Cl. 257/678; 438/106; 438/111; 257/780

(57) ABSTRACT

A method of fabricating a semiconductor package includes: forming a circuit pattern on a frame; attaching a semiconductor chip onto the circuit pattern; connecting the semiconductor chip and the circuit pattern electrically; forming a molding wrapping the semiconductor chip and the circuit pattern; removing the frame; forming a photoresist film having a through hole on the circuit pattern, the through hole exposing a portion of the circuit pattern; and forming a solder ball on the photoresist film, the solder ball being connected to the portion of the circuit pattern through the through hole.

This application claims the benefit of Korean Patent Application No. 2003-0030430, filed on May 14, 2003, which is hereby incorporated by reference.

### BACKGROUND OF THE INVENTION

1. Field of the Invention

The present invention relates to a semiconductor package, and more particularly, to a metal chip scale semiconductor package and a method fabricating the same.

2. Discussion of the Related Art

In general, a semiconductor package means an individual semiconductor chip molded on a substrate such as a lead frame and a printed circuit board (PCB) using an epoxy molding compound (EMC). The semiconductor chip may be obtained through a process of sawing a wafer and the semiconductor package has input and output terminals exterior thereof. The reasons for molding are to protect the semiconductor chip from several exterior circumstances such as dust, moisture, electric load and mechanical load and to optimize and maximize electric properties of the semiconductor chip. The semiconductor package is mounted on a main board or a PCB to function as an electric element for an electronic information apparatus.

Recently, as a speed and a function of an electronic information apparatus increase, a larger amount of memory is required, and weight and size of the electronic information apparatus are reduced. Accordingly, various packaging methods for small size and weight and high-pin have been suggested. In addition, development target of the packaging method is transferred from an insert mounted type such as dual in-line package (DIP) to a surface mounted type such as thin small out-package (TSOP) and thin quad flat package (TQFP). Among various packaging methods, a metal chip scale packaging method has been a subject of recent research and development. Especially, a metal chip scale packaging method of a ball grid array (BGA) type is widely used. In a metal chip scale packaging method of a BGA type, a mounting substrate of an insulating material such as glass fiber, epoxy resin and polyimide resin having circuit patterns of copper is used as a base frame instead of a lead frame.

FIG. 1 is a schematic cross-sectional view showing a semiconductor package of a ball grid array type according to the related art. In FIG. 1, a semiconductor chip 1 obtained through a process of sawing a wafer is attached onto a first surface of a mounting substrate 2 using an insulating adhesive 4. A bonding pad (not shown) of the semiconductor chip 1 is electrically connected to a circuit pattern 3 printed on the mounting substrate 2 through a wire 5. The semiconductor chip 1, the mounting substrate 2 and the wire 5 are molded using an epoxy molding compound (EMC) to form a molding 6. A solder ball 7 is formed on second surface of the mounting substrate 2. The solder ball 7 is electrically connected to the circuit pattern 3 exposed through a through hole 2a of the mounting substrate 2.

In a semiconductor package of a BGA type, however, the circuit pattern 3 is further formed on the mounting substrate 2. In addition, since the through hole 2a is formed in the mounting substrate 2 and the solder ball 7 for electric connection is formed through the through hole 2a, fabrication cost increases. Moreover, reliability of the semiconductor package is reduced due to infiltration of moisture through a gap 8 between the molding 6 and the mounting substrate 2. The moisture may expand between the gap 8 by heat or thermal stress during a soldering step for connection of the semiconductor package and an external circuit and the expansion of moisture causes cracks in the semiconductor package.

### SUMMARY OF THE INVENTION

Accordingly, the present invention is directed to a chip scale semiconductor package and a method of fabricating the same that substantially obviate one or more of the problems due to limitations and disadvantages of the related art.

An object of the present invention is to provide a chip scale semiconductor package and a method of fabricating the same where production cost is reduced and reliability is improved.

An advantage of the present invention is to provide a chip scale semiconductor package and a method of fabricating the same where a mounting substrate is not used and infiltration of moisture is prevented.

Additional features and advantages of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described, a method of fabricating a semiconductor package includes: forming a circuit pattern on a frame; attaching a semiconductor chip onto the circuit pattern; connecting the semiconductor chip and the circuit pattern electrically; forming a molding wrapping the semiconductor chip and the circuit pattern; removing the frame; forming a photoresist film having a through hole on the circuit pattern, the through hole exposing a portion of the circuit pattern; and forming a solder ball on the photoresist film, the solder ball being connected to the portion of the circuit pattern through the through hole.

In another aspect, a semiconductor package includes: a photoresist film having a through hole; a circuit pattern on one surface of the photoresist film; a solder ball on an opposite surface of the photoresist film, the solder ball being connected to the circuit pattern through the through hole; a semiconductor chip on the circuit pattern; an electric connection means connecting the semiconductor chip and the circuit pattern; and a molding wrapping the semiconductor chip, the circuit pattern and the electric connection means.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic cross-sectional view showing a semiconductor package of a ball grid array type according to the related art;

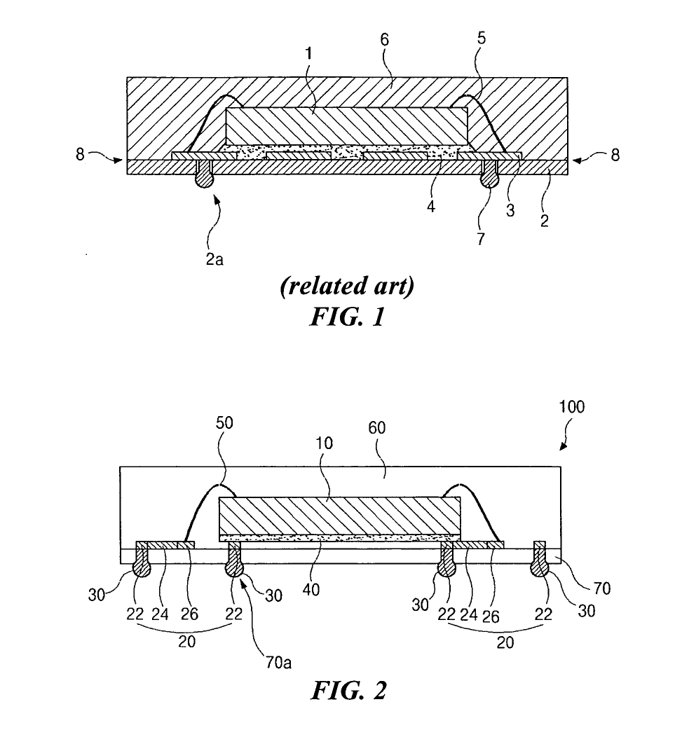

FIG. 2 is a schematic cross-sectional view of a metal chip scale semiconductor package according to an embodiment of the present invention;

FIG. 3A is a schematic plane view of a metal chip scale semiconductor package according to an embodiment of the present invention;

FIG. 3B is a magnified view of a portion “A” of FIG. 3A;

FIG. 4 is a flow chart illustrating a fabricating process of a metal chip scale semiconductor package according to an embodiment of the present invention;

FIGS. 5A to 5J are schematic cross-sectional views, which are taken along a line “V-V” of FIG. 4, showing a fabricating process of a metal chip scale semiconductor package according to an embodiment of the present invention;

FIG. 6 is a magnified view of a portion “B” of FIG. 5C; and

FIG. 7 is a magnified view of a portion “A” of FIG. 5D.

### DETAILED DESCRIPTION OF THE ILLUSTRATED EMBODIMENTS

Reference will now be made in detail to embodiments of the present invention, example of which is illustrated in the accompanying drawings. Wherever possible, similar reference numbers will be used throughout the drawings to refer to the same or like parts.

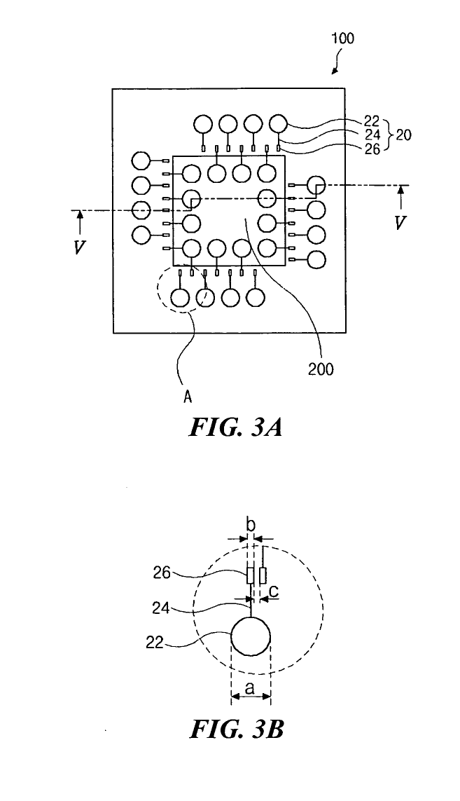

FIG. 2 is a schematic cross-sectional view of a metal chip scale semiconductor package according to an embodiment of the present invention.

In FIG. 2, a metal chip scale semiconductor package 100 includes a semiconductor chip 10, a circuit pattern 20, a wire 50 connecting the semiconductor chip 10 and the circuit pattern 20, a molding 60 wrapping the semiconductor chip 10, the circuit pattern 20 and the wire 50, a photoresist (PR) film 70 and a solder ball 30. The circuit pattern 20 includes a solder ball pad 22, a bonding lead 26 and a signal line 24 connecting the solder ball pad 22 and the bonding lead 26. The wire 50 may includes gold (Au). The semiconductor chip 10 may be attached onto the circuit pattern 20 with an adhesive 40 such as a double-faced tape. The PR film 70 has a through hole 70a exposing a solder ball pad 22 and the solder ball 30 is connected to the solder ball pad 22 though the through hole 70a.

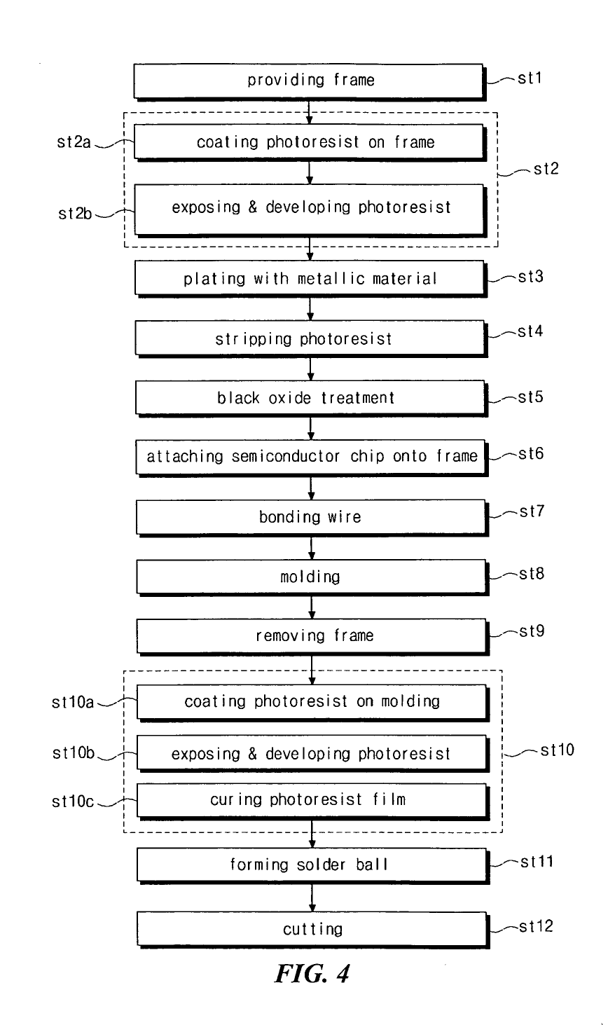

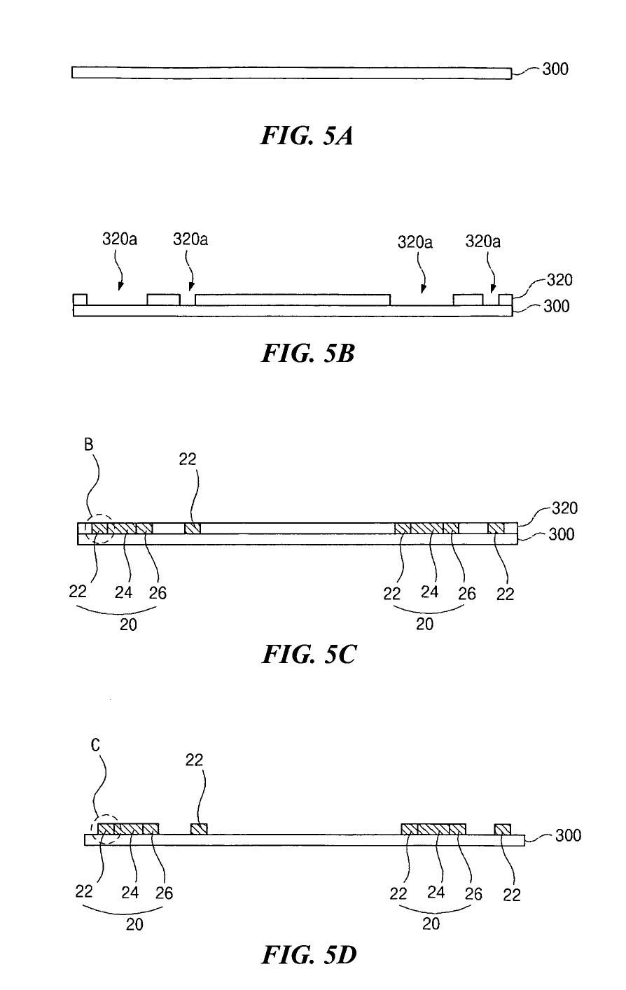

FIG. 3A is a schematic plane view of a metal chip scale semiconductor package according to an embodiment of the present invention and FIG. 3B is a magnified view of a portion “A” of FIG. 3A.

In FIG. 3A, a metal chip scale semiconductor package 100 has a die pad region 200 at a central portion thereof. A circuit pattern 20 including a solder ball pad 22, a signal line 24 and a bonding lead 26 is formed in the metal chip scale semiconductor package 100. The solder ball pad 22 is alternately disposed inside and outside the die pad region 200 and the bonding lead 26 is disposed outside the die pad region 200. The solder ball pad 22 is connected to the bonding lead 26 through the signal line 24. Even though not shown in FIG. 3A, a semiconductor chip may be disposed in the die pad region 200 and the bonding lead 26 may be connected to the semiconductor chip through a wire. Since the bonding lead 26 has a size smaller than that of the solder ball pad 22, higher number of bonding lead 26 may be disposed at a periphery of the die pad region 200 than the solder ball pad 22. In other words, the solder ball pad 22 is disposed at both inside and outside of the die pad region 200 and the bonding lead 26 is closely disposed at a periphery of the die pad region 200. Accordingly, the metal chip scale semiconductor package 100 may be easily applied to a high pin package.

In FIG. 3B, a first width “a” of the solder ball pad 22 is generally within a range of about 250 μm to about 300 μm. In addition, a second width “b” of the bonding lead 26 is about 40 μm and a third width “c” between the adjacent bonding leads 26 is within a range of about 30 μm to about 40 μm. Since the first width “a” is greater than a sum of the second and third widths “b” and “c,” the bonding lead 26 may be disposed more closely than the solder ball 22 and the number of the bonding leads at the periphery of the die pad region 200 (of FIG. 3A) may correspond to the number of pins of the semiconductor chip (high pin).

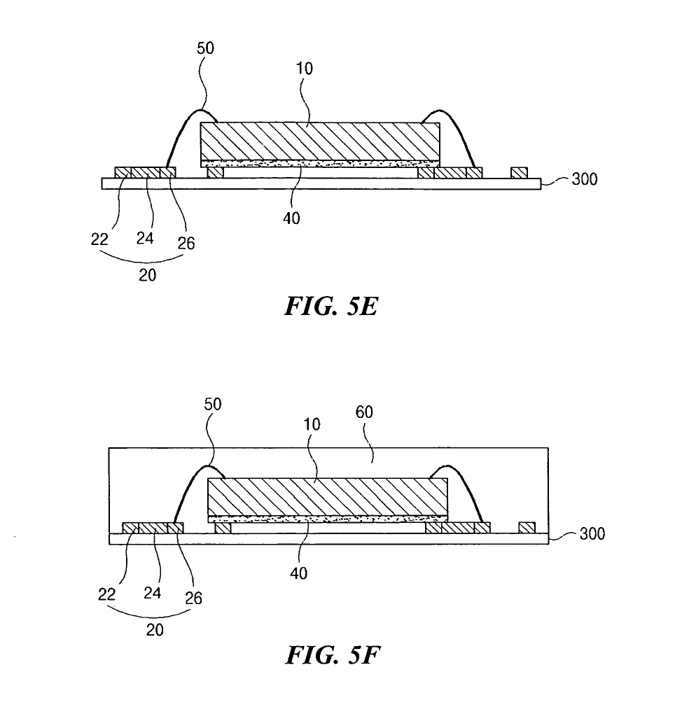

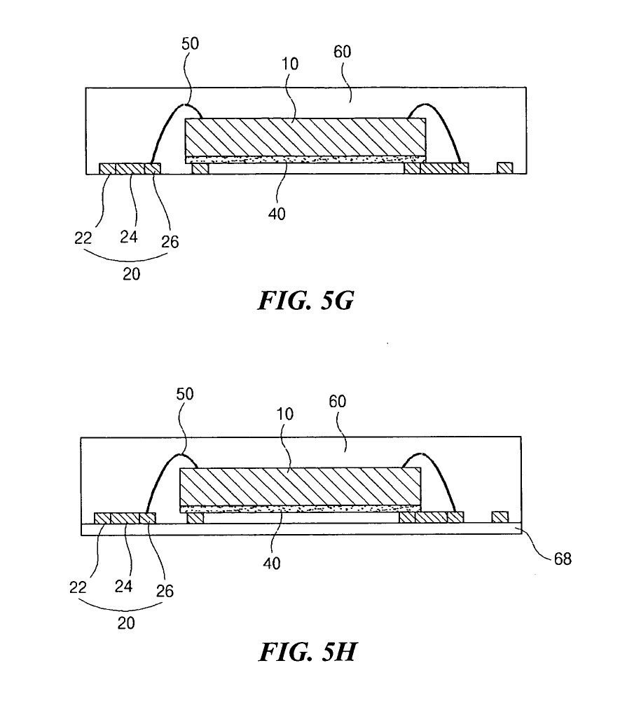

FIG. 4 is a flow chart illustrating a fabricating process of a metal chip scale semiconductor package according to an embodiment of the present invention and FIGS. 5A to 5J are schematic cross-sectional views, which are taken along a line “V-V” of FIG. 4, showing a fabricating process of a metal chip scale semiconductor package according to an embodiment of the present invention.

In FIGS. 4 and 5A, a frame 300 having a plate shape is provided (stl). The frame may include one of copper (Cu), copper (Cu) alloy, iron (Fe) and iron (Fe) alloy.

In FIGS. 4 and 5B, a photoresist (PR) pattern 320 is formed on the frame 300 through a photolithographic process. After coating a photoresist (PR) on the frame 300 (st2a), the coated PR is exposed and developed using a mask to form the PR pattern 320 (st2b). The PR may be a positive type or a negative type. The PR pattern 320 has a plurality of holes 320a corresponding to a circuit pattern 20 (of FIG. 3) including a solder ball pad 22 (of FIG. 3), a bonding lead 26 (of FIG. 3) and a signal line 24 (of FIG. 3). The frame 300 is exposed through the plurality of holes 320a.

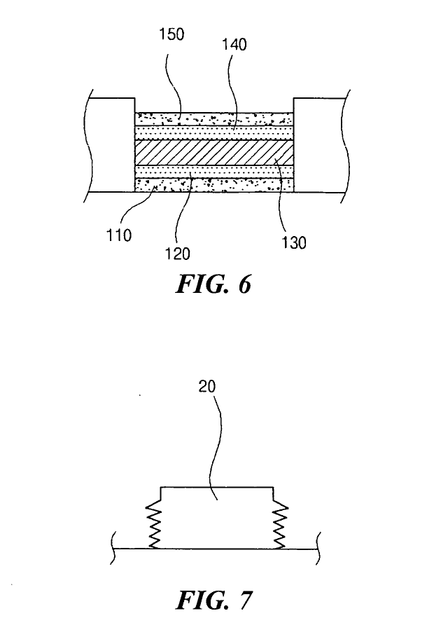

In FIGS. 4 and 5C, a circuit pattern 20 including a solder ball pad 22, a bonding lead 26 and a signal line 24 are formed in the plurality of holes 320a (st3). The circuit pattern 20 may be formed by a plating method using a metallic material. The metallic material may include at least one of copper (Cu), copper (Cu) alloy, gold (Au) and nickel (Ni) as a single layer or a multiple layer. Since copper (Cu) has a high melting temperature and is apt to be oxidized at a surface thereof, adhesion property of a copper (Cu) layer is poor. In order to improve adhesion property, gold (Au) may be plated on and under the copper (Cu) layer. However, since a gold (Au) layer has micro pores due to porosity, copper (Cu) of the copper (Cu) layer may be diffused into the gold (Au) layer. To prevent the diffusion, a nickel (Ni) layer may be formed between the copper (Cu) layer and the gold (Au) layer as a barrier layer. A copper (Cu) layer has similar problems. A multiple layer of metallic material for the circuit pattern 20 is illustrated in FIG. 7.

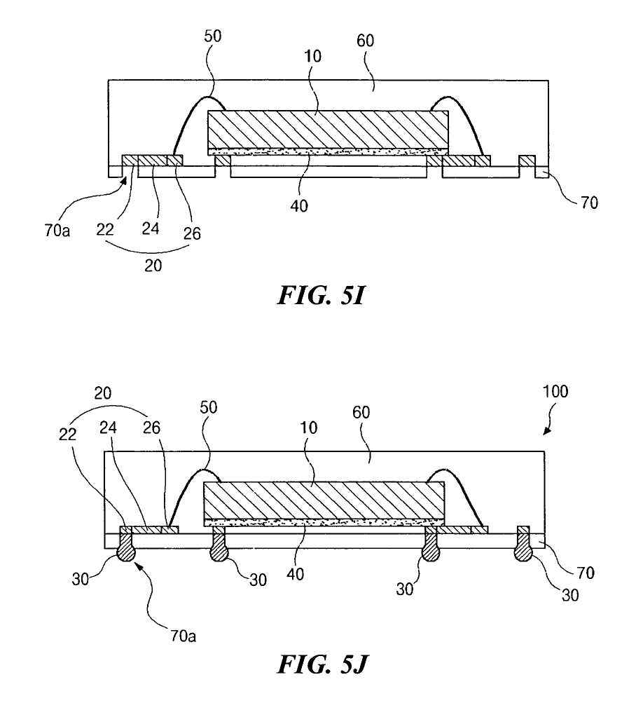

FIG. 6 is a magnified view of a portion “B” of FIG. 5C.

In FIG. 6, a first gold (Au) layer 110 is formed on the frame 300 (of FIG. 5C) and a first nickel (Ni) layer 120 is formed on the first gold (Au) layer 110. A copper (Cu) layer 130 is formed on the first nickel (Ni) layer 120. A copper (Cu) alloy layer may be formed on the first nickel (Ni) layer 120 instead of the copper (Cu) layer 130. A second nickel (Ni) layer 140 is formed on the copper (Cu) layer 130 and a second gold (Au) layer 150 is formed on the second nickel (Ni) layer 140. Since the copper (Cu) layer 130 functions as a main layer, the copper (Cu) layer 130 has a thickness greater than those of any other layers. A multiple layer of the first gold (Au) layer 110, the first nickel (Ni) layer 120, the copper (Cu) layer 130, the second nickel (Ni) layer 140 and the second gold (Au) layer 150 has a thickness greater than about 50 μm to prevent infiltration of moisture. However, since the infiltration of moisture is reduced by a subsequent black oxide treatment, the thickness of the multiple layer may be reduced to about 20 μm.

As referring again to FIGS. 4 and 5D, the PR pattern 320 (of FIG. 5C) is stripped to remain the circuit pattern 20 including the solder ball pad 22, the bonding lead 26 and the signal line 24 on the frame 300 (st4). A cleaning step may be performed after the stripping step and then a black oxide treatment may be performed for a side surface of the circuit pattern 20 (st5). In the black oxide treatment, a surface of copper (Cu) or copper (Cu) alloy is treated with an alkali solution such as sodium hydrochlorite and sodium hydroxide under a temperature of about 100° C. for about 1 min to about 10 min to form needle-shaped crystalline cupric oxide (CuO).

FIG. 7 is a magnified view of a portion “A” of FIG. 5D.

As shown in FIG. 7, the side surface of the circuit pattern 20 has a needle shape. In a subsequent molding step, a bonding force between the circuit pattern 20 and an epoxy molding compound (EMC) increases and infiltration of moisture is prevented due to a needle shape of the circuit pattern 20. Accordingly, a thickness of the circuit pattern 20 may be reduced to about 20 μm, thereby fabrication time and cost for plating step of the circuit pattern 20 reduced and productivity dramatically improved.

In addition, as a thickness of the circuit pattern 20 decreases, a resolution of the PR pattern 320 (of FIG. 5C) increases. When the circuit pattern 20 has a thickness of about 50 μm, the PR pattern 320 (of FIG. 5C) also has a thickness of about 50 μm. Since a resolution of the PR pattern 320 (of FIG. 5C) having a thickness of about 50 μm is poor, a fine PR pattern may not be obtained with a thickness of about 50 μm and the poor resolution may cause limitations in fabrication process of a semiconductor package having high pin. In other words, since a thickness of the PR pattern 320 (of FIG. 5C) is the same as that of the circuit pattern 20, the thickness of the PR pattern 320 (of FIG. 5C) may be reduced and a fine PR pattern may be obtained by reduction of the thickness of the circuit pattern 20. Therefore, an amount of PR may be reduced and a fine PR pattern may be obtained by the black oxide treatment.

As referring again to FIGS. 4 and 5E, a semiconductor chip 10 is attached onto the frame 300 having the circuit pattern 20 with an adhesive 40 such as a double-faced tape (st6). A wire 50 is bonded to a bonding pad (not shown) of the semiconductor chip 10 and the bonding lead 24 of the circuit pattern 20, thereby the bonding pad and the bonding lead 24 electrically connected to each other (st7). The wire 50 may include gold (Au) and may be bonded through one of a thermo compression bonding method, an ultrasonic bonding method and a thermosonic bonding method.

In FIGS. 4 and 5F, a molding 60 is formed on the semiconductor chip 10 using an epoxy molding compound (EMC) (st8). The molding 60 wrapping the semiconductor chip 10, the circuit pattern 20 and the wire 50 may include epoxy resin and may be formed through one of a molding method and a potting method. The molding 60 is formed in a space between the adhesive 40 and the frame 300 to prevent infiltration of moisture.

In FIGS. 4 and 5, the frame 300 is removed and the circuit pattern 20 is exposed (st9). The frame 300 may be removed through a dipping method. For example, the frame 300 may be etched away by dipping the molding 60 having the frame 300 into an etchant, thereby the circuit pattern 20 including the solder ball pad 22, the bonding lead 26 and the signal line 24 exposed.

In FIGS. 4, 5H and 5I, a photoresist (PR) film 70 having a through hole 70a is formed on the circuit pattern 20 through a photolithographic process (st10). A PR layer 68 may be formed on the circuit pattern 20 by coating photoresist (PR) (st10a), and then the PR layer 68 may be exposed and developed using a mask to form the PR film 70 (st10b). The PR film 70 may be cured after development step (st10c). Since the through hole 70a corresponds to the solder ball pad 22, the solder ball pad 22 is exposed through the through hole 70a, and the bonding lead 26 and the signal line 24 are covered with the PR film 70. Accordingly, the bonding lead 26 and the signal line 24 are separated from exterior and damages to the bonding lead 26 and the signal line 24 are prevented.

In FIGS. 4 and 5J, a solder ball 30 is formed on the PR film 70 (st11). The solder ball 30 is connected to the solder ball pad 22 through the through hole 70a. The solder ball 30 may be formed through one of a solder ball attaching method and a solder dipping method using an electrolyte. For fabrication efficiency, a plurality of metal chip scale semiconductor packages may be formed on a large-sized frame and the plurality of metal chip scale semiconductor packages may be separated apart by a cutting step after forming the solder ball 30 (st12) to obtain a metal chip scale semiconductor package 100. The metal chip scale semiconductor package 100 is connected to an external circuit by attaching the solder ball 22 onto a terminal of a main board or a printed circuit board (PCB).

Even though a semiconductor package using a wire bonding is illustrated in the embodiment, the present invention may be applied to every kind of semiconductor packages such as flip chip package. In addition, since a circuit pattern is obtained through a photolithographic process of a frame without using a mounting substrate, production cost is reduced. Moreover, a bonding force between a circuit pattern and a molding is improved and infiltration of moisture is effectively prevented by black oxide treatment for a side surface of a circuit pattern. Therefore, a thickness of a photoresist film for a circuit pattern is dramatically reduced, thereby production cost further reduced and productivity improved.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method of fabricating a semiconductor package, comprising:
forming a circuit pattern on a frame;
attaching a semiconductor chip onto the circuit pattern;
connecting the semiconductor chip and the circuit pattern electrically;
forming a molding wrapping the semiconductor chip and the circuit pattern;
removing the frame;
forming a photoresist film having a through hole on the circuit pattern, the through hole exposing a portion of the circuit pattern; and
forming a solder ball on the photoresist film, the solder ball being connected to the portion of the circuit pattern through the through hole.

2. The method according to claim 1, wherein the step of forming the circuit pattern comprises:
coating a photoresist on the frame;
exposing the coated photoresist using a mask;
developing the exposed photoresist to form a photoresist pattern having a plurality of holes exposing the frame;
plating the frame exposed through the plurality of holes with a metallic material to form the circuit pattern;
stripping the photoresist pattern; and
performing a black oxide treatment for the circuit pattern to have a needle-shaped side surface.

3. The method according to claim 2, wherein the step of plating the frame comprises:
plating the frame with gold (Au) to form a first gold (Au) layer in the plurality of holes;
plating the first gold (Au) layer with nickel (Ni) to form a first nickel (Ni) layer in the plurality of holes;
plating the first nickel (Ni) layer with one of copper (Cu) and copper (Cu) alloy to form a copper (Cu) layer in the plurality of holes;
plating the copper (Cu) layer with nickel (Ni) to form a second nickel (Ni) layer in the plurality of holes; and
plating the second nickel (Ni) layer with gold (Au) to form a second gold (Au) layer in the plurality of holes.

4. The method according to claim 1, wherein the step of attaching the semiconductor chip comprises:
attaching a double-faced tape onto the circuit pattern; and
fixing the semiconductor chip on the double-faced tape.

5. The method according to claim 1, wherein the semiconductor chip is connected to the circuit pattern through a gold (Au) wire

6. The method according to claim 5, wherein the gold (Au) wire is bonded through one of a thermo compression bonding method, an ultrasonic bonding method and a thermosonic bonding method.

7. The method according to claim 1, wherein the molding is formed through one of a molding method and a potting method.

8. The method according to claim 1, wherein the frame includes one of copper (Cu), copper (Cu) alloy, iron (Fe) and iron (Fe) alloy.

9. The method according to claim 8, wherein the frame is removed by dipping the molding having the frame into an etchant.

10. The method according to claim 1, wherein the circuit pattern includes a solder ball pad, a bonding lead and a signal line connected to the solder ball pad and the bonding lead.

11. The method according to claim 10, wherein the photoresist film covers the bonding lead and the signal line and the through hole exposes the solder ball pad.

12. The method according to claim 1, wherein the step of forming the photoresist film comprises:
coating a photoresist on the circuit pattern;
exposing the coated photoresist using a mask;
developing the exposed photoresist to form the photoresist film having the through hole; and
curing the photoresist film.

13. The method according to claim 1, further comprising cutting the molding into pieces.

14. A semiconductor package, comprising:
a photoresist film having a through hole;
a circuit pattern on one surface of the photoresist film;
a solder ball on an opposite surface of the photoresist film, the solder ball being connected to the circuit pattern through the through hole;
a semiconductor chip on the circuit pattern;
an electric connection means connecting the semiconductor chip and the circuit pattern; and
a molding wrapping the semiconductor chip, the circuit pattern and the electric connection means.

15. The package according to claim 14, wherein the circuit pattern includes a solder ball pad, a bonding lead and a signal line connected to the solder ball pad and the bonding lead.

16. The package according to claim 15, wherein the photoresist film covers the bonding lead and the signal line and the through hole exposes the solder ball pad, wherein the solder ball pad overlaps the semiconductor chip.

17. The package according to claim 14, wherein the circuit pattern has a needle-shaped side surface.

18. The package according to claim 14, wherein the circuit pattern includes a first gold (Au) layer, a first nickel (Ni) layer on the first gold (Au) layer, a copper (Cu) layer on the first nickel (Ni) layer, a second nickel (Ni) layer on the copper (Cu) layer and a second gold (Au) layer on the second nickel (Ni) layer.

19. The package according to claim 14, wherein the electric connection means is a gold (Au) wire.

20. The package according to claim 14, further comprising a double-faced tape between the circuit pattern and the semiconductor chip.
